(19) United States
(12) Patent Application Publication
(10) Pub. No.: US 2022/0038076 A1
(43) Pub. Date: Feb. 3, 2022

(54) AIR-GAP TYPE FILM BULK ACOUSTIC RESONATOR

(71) Applicant: WISOL CO., LTD., Gyeonggi-do (KR)

(72) Inventors: Yong Hun KO, Gyeonggi-do (KR); Byung Hun KIM, Gyeonggi-do (KR); Sang Ik HAN, Gyeonggi-do (KR)

(73) Assignee: WISOL CO., LTD.

(21) Appl. No.: 17/186,088

(22) Filed: Feb. 26, 2021

(30) Foreign Application Priority Data
Jul. 31, 2020 (KR) 10-2020-0095637

(51) Int. Cl. H03H 9/17; H03H 9/02

(52) U.S. Cl. CPC H03H 9/173; H03H 9/02015

(57) ABSTRACT

Disclosed is an air-gap type film bulk acoustic resonator (FBAR) including a substrate including an air-gap portion which has a substrate cavity and is formed in a top surface, a lower electrode formed above the substrate, a piezoelectric layer formed above the lower electrode, and an upper electrode formed above the piezoelectric layer and having one side on which an electrode edge is formed to be adjacent to a vertical virtual boundary of a sidewall of the air-gap portion. Here, the piezoelectric layer includes a piezoelectric cavity formed below the electrode edge.

### CROSS-REFERENCE TO RELATED APPLICATION

This application claims priority to and the benefit of Korean Patent Application No. 10-2020-0095637, filed on Jul. 31, 2020, the disclosure of which is incorporated herein by reference in its entirety.

### FIELD

The present invention relates to a resonator used for communication in a radio frequency band, and more particularly, to an air-gap type thin film bulk acoustic resonator (FBAR).

### BACKGROUND

Wireless mobile communication technology requires a variety of radio frequency (RF) components capable of efficiently transmitting information within a limited frequency band. Particularly, among RF components, a filter is one of essential components used in mobile communication technology and enables high-quality communication by selecting a signal needed by a user among a plurality of frequency bands or filtering a signal to be transmitted.

Currently, a dielectric filter and a surface acoustic wave (SAW) filter are used most as an RF filter for wireless communication. The dielectric filter has advantages such as a high dielectric constant, a low insertion loss, stability at a high temperature, high vibration resistance, and high shock resistance. However, the dielectric filter has a limitation in miniaturization and monolithic microwave integrated circuit (MMIC) which are recent trends of technology development. Also, the SAW filter has a small size in comparison to the dielectric filter, easily processes a signal, has a simple circuit, and is manufactured using a semiconductor process so as to facilitate mass production. Also, the SAW filter has an advantage of transmitting and receiving high-grade information due to higher side rejection within a passband in comparison to the dielectric filter. However, since an SAW filter process includes an exposure process using ultraviolet (UV), there is a disadvantage in which a line width of an interdigital transducer (IDT) has a limitation of about 0.5 μm. Accordingly, there is a problem in which it is impossible to cover an ultrahigh frequency band of 5 GHz or more using the SAW filter. Basically, there is a difficulty in forming an MMIC structure and a single chip on a semiconductor substrate.

In order to overcome such limitations and problems, a film bulk acoustic resonator (FBAR) filter integrated with other active devices on an existing semiconductor (Si or GaAs) substrate to completely implement a frequency control circuit as an MMIC is provided.

The FBAR is a thin film device which is low-cost, small-sized, and features high quality coefficient so as to be applicable to a wireless communication device, a military-use radar in a variety of frequency bands of 900 MHz to 10 GHz. Also, the FBAR is reduced in size as one-several hundredth of the dielectric filter and a lumped constant (LC) filter and has a very smaller insertion loss than the SAW filter. Accordingly, it is apparent that the FBAR is most adequate device for an MMIC which requires high stability and a high quality coefficient.

An FBAR filter is formed by depositing zinc oxide (ZnO), aluminum nitride (AlN), or the like which is a piezoelectric-dielectric material on Si or GaAs which is a semiconductor substrate using an RF sputtering method and causes resonation due to a piezoelectric property. That is, the FBAR generates resonance by depositing a piezoelectric film between both electrodes and causing a bulk acoustic wave.

A variety of forms of FBAR structures have been studied until now. In the case of a membrane type FBAR, a silicon oxide film (SiO₂) is deposited on a substrate and a membrane layer is formed using a cavity formed through isotropic etching on an opposite side of the substrate. Also, a lower electrode is formed above the silicon oxide film, a piezoelectric layer is formed by depositing a piezoelectric material above the lower electrode using an RF magnetron sputtering, and an upper electrode is formed above the piezoelectric layer.

The above membrane type FBAR has an advantage of less dielectric loss and power loss due to the cavity. However, the membrane type FBAR has problems in which an area occupied by a device is large due to a directivity of the silicon substrate and a yield is decreased by damages due to low structural stability in a follow-up packaging process. Accordingly, recently, in order to reduce a loss caused by the membrane and to simplify a device manufacturing process, an air-gap type FBAR and a Bragg reflector type FBAR have appeared.

The Bragg reflector type FBAR has a structure in which a reflection layer is formed by depositing materials having a high elastic impedance difference on every other layer on a substrate and a lower electrode, a piezoelectric layer, and an upper electrode are sequentially deposited. Here, elastic wave energy which has passed through the piezoelectric layer is not transferred toward the substrate and all reflected by the reflection layer so as to generate efficient resonation. Although the Bragg reflector type FBAR is structurally firm and has no stress caused by bending, it is difficult to form four or more reflection layers having a precise thickness for total reflection and large amounts of time and cost are necessary for manufacturing.

Meanwhile, in an existing air-gap type FBAR having a structure in which a substrate and a resonance portion are isolated using an air gap instead of a reflection layer, a sacrificial layer is implemented by performing isotropic etching on a surface of a silicon substrate and is surface-polished through chemical-mechanical polishing, an insulation layer, a lower electrode, a piezoelectric layer, and an upper electrode are sequentially deposited, and an air gap is formed by removing the sacrificial layer through a via hole so as to implement an FBAR.

In general, a piezoelectric layer is formed between upper and lower electrodes in an FBAR structure, and the upper and lower electrodes are installed in only a necessary area so as to use a piezoelectric effect. Accordingly, a mechanical anchor loss is great such that reduction in mechanical energy is caused.

In the case of the upper electrode or lower electrode, molybdenum (Mo), ruthenium (Ru), tungsten (W), and the like are used to increase acoustic impedance. Since a skin depth of an electrode material is determined according to a frequency of a filter and a thickness significantly smaller than the skin depth is generally used, it is impossible to transfer charges at a resonance point of the piezoelectric layer, a quality factor is reduced.

### RELATED ART DOCUMENT

### Patent Document

Patent Document 1: Korean Patent Publication No. 10-2004-0102390 (published on Dec. 8, 2004)

### SUMMARY

The present invention is directed to providing an air-gap type film bulk acoustic resonator (FBAR) in which a piezoelectric cavity is provided below an electrode edge of an upper electrode in the FBAR including a lower electrode, the upper electrode, and a piezoelectric layer so as to reduce an anchor loss (mechanical loss) as well as increasing a quality factor.

According to an aspect of the present invention, there is an air-gap type FBAR including a substrate including an air-gap portion which has a substrate cavity and is formed in a top surface, a lower electrode formed above the substrate, a piezoelectric layer formed above the lower electrode, and an upper electrode formed above the piezoelectric layer and having one side on which an electrode edge is formed to be adjacent to a vertical virtual boundary of a sidewall of the air-gap portion. Here, the piezoelectric layer includes a piezoelectric cavity formed below the electrode edge.

The piezoelectric cavity may include a cavity area formed by a cavity bottom surface formed by exposing a part of a top of the piezoelectric layer, a cavity inner wall vertically formed inside the upper electrode on the basis of the electrode edge, and a cavity outer wall vertically formed outside the upper electrode.

A distance between the cavity inner wall and the electrode edge on a vertical cross section with respect to each of sides in a polygonal structure of the air-gap type FBAR may be different for each of the sides.

The air-gap type FBAR may further include a protective layer formed above the upper electrode.

A protective edge corresponding to an end of the protective layer may coincide with an end of the electrode edge.

A protective edge corresponding to an end of the protective layer may not coincide with an end of the electrode edge.

The protective layer may protrude from the electrode edge by a certain length or longer or the upper electrode may protrude from the protective edge by a certain length or longer.

The certain length may be a length increased or decreased within a range of 50% of a protruding length of the upper electrode protruding from the cavity inner wall.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view of an air-gap type film bulk acoustic resonator (FBAR) 100 according to a first embodiment of the present invention;

FIG. 2A is a vertical cross-sectional view taken along one side AA′ of the air-gap type FBAR 100 shown in FIG. 1;

FIG. 2B is a vertical cross-sectional view taken along another side BB′ of the air-gap type FBAR 100 shown in FIG. 1;

FIG. 2C is a vertical cross-sectional view taken along still another side CC′ of the air-gap type FBAR 100 shown in FIG. 1;

FIG. 3 is a graph illustrating that it is possible to apply a resonance mode which varies according to a distance between a cavity inner wall and an electrode edge;

FIG. 4 is a vertical cross-sectional view of an air-gap type FBAR 200 according to a second embodiment of the present invention; and

FIG. 5 is a graph illustrating an improvement degree of a quality factor according to a protruding length of a protective edge 150-1 of a protective layer.

### DETAILED DESCRIPTION

Hereinafter, exemplary embodiments of the present invention will be described in detail with reference to the attached drawings.

The embodiments of the present invention are provided to more completely explain the present invention to one of ordinary skill in the art. The embodiments of the present invention may be changed in a variety of shapes, and the scope of the present invention is not limited to the following embodiments. The embodiments are provided to make the present disclosure more substantial and complete and to completely transfer the concept of the present invention to those skilled in the art.

The terms are used herein to explain particular embodiments and not intended to limit the present invention. As used herein, singular expressions, unless clearly defined otherwise in context, include plural expressions. Also, as used herein, the term “and/or” includes any and all combinations or one of a plurality of associated listed items. Also, hereinafter, the embodiments of the present invention will be described with reference drawings which schematically illustrate the embodiments of the present invention.

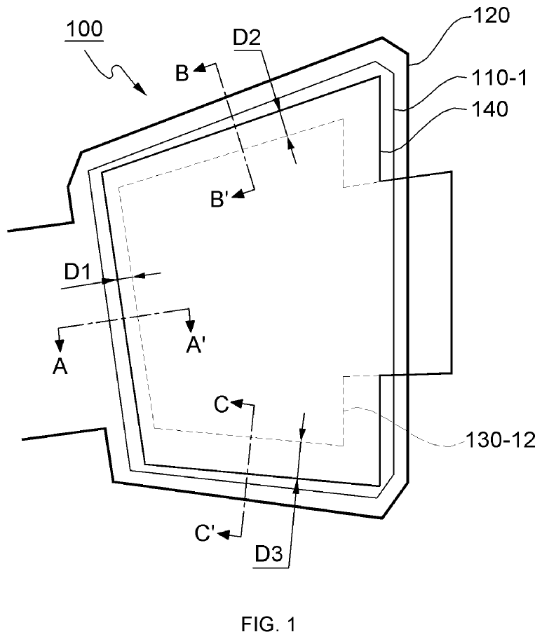

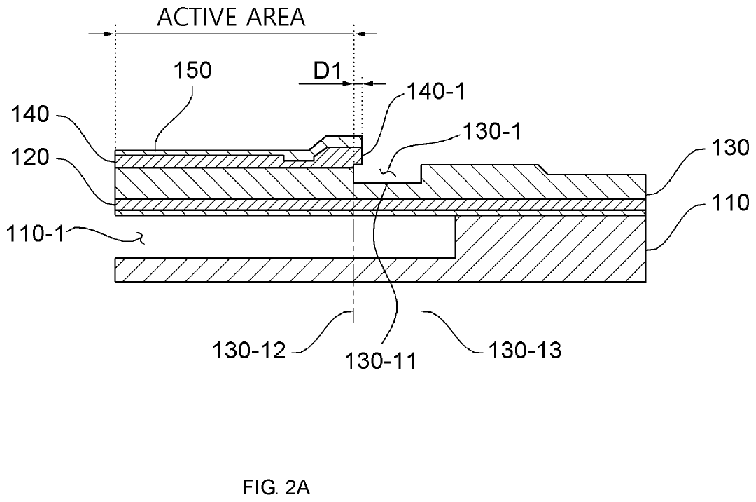

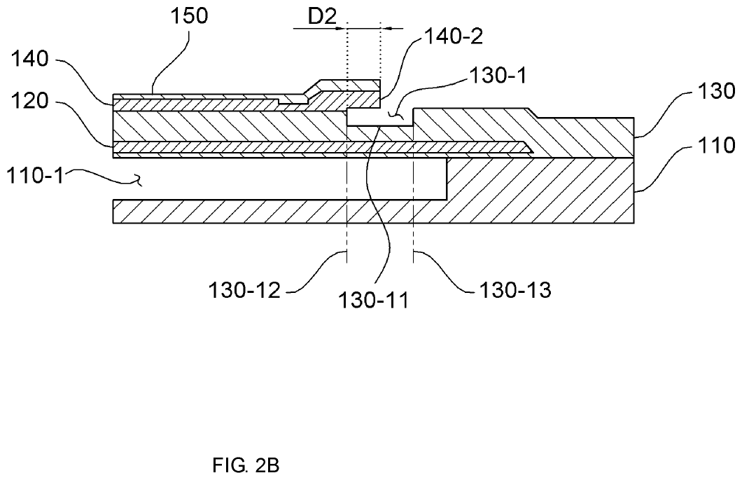

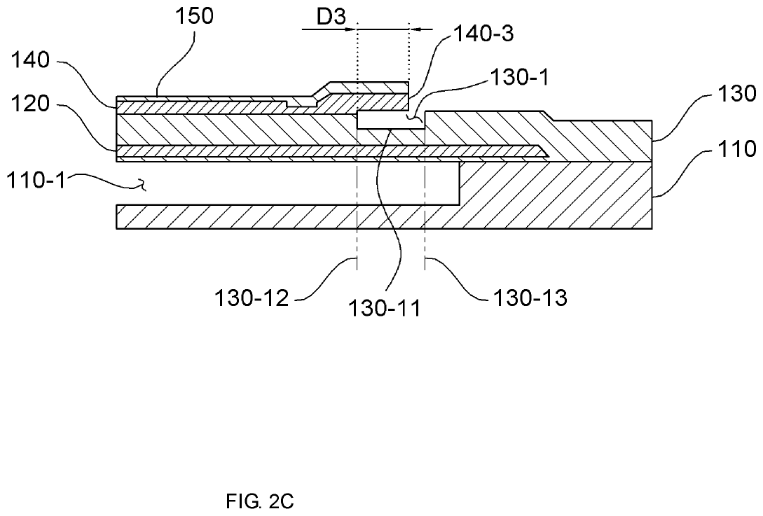

FIG. 1 is a plan view of an air-gap type film bulk acoustic resonator (FBAR) 100 according to a first embodiment of the present invention, FIG. 2A is a vertical cross-sectional view taken along one side AA′ of the air-gap type FBAR 100 shown in FIG. 1, FIG. 2B is a vertical cross-sectional view taken along another side BB′ of the air-gap type FBAR 100 shown in FIG. 1, and FIG. 2C is a vertical cross-sectional view taken along still another side CC′ of the air-gap type FBAR 100 shown in FIG. 1.

Referring to FIGS. 1 and 2A to 2C, the air-gap type FBAR 100 according to the first embodiment includes a substrate 110, an air-gap portion 110-1, a lower electrode 120, a piezoelectric layer 130, an upper electrode 140, and a protective layer 150.

When a signal is applied from the outside between the lower electrode 120 and the upper electrode 140, the air-gap type FBAR 100 resonates with respect to a frequency of natural oscillation according to a thickness of the piezoelectric layer 130 while part of electrical energy input and transferred between the two electrodes is converted into mechanical energy according to a piezoelectric effect and is converted again into electrical energy. Here, the air-gap type FBAR 100 may have a polygonal structure (for example, a quadrangular structure) when viewed from above.

The substrate 110 is a semiconductor substrate, and a general silicon wafer may be used. Preferably, a high resistivity silicon substrate (HRS) may be used. An insulation layer (not shown) may be formed on a top surface of the substrate 100. As the insulation layer, a thermal oxidation layer, which is easily growable on the substrate 100, may be employed or an oxide film or a nitride film formed using a general deposition process such as chemical vapor deposition and the like may be selectively employed.

The air-gap portion 110-1 is formed by forming a substrate cavity in the substrate 110, forming an insulation layer on the substrate cavity, depositing a sacrificial layer above the insulation layer, etching and planarizing the sacrificial layer, and removing the sacrificial layer. Here, the sacrificial layer is formed using a material such as polysilicon, tetraethyl orthosilicate (TEOS), phosphosilicate glass (PSG), and the like, which has excellent surface roughness and is easily formed or removed. As an example, a sacrificial layer may employ polysilicon which has high surface roughness. The sacrificial layer may be easily formed or removed using polysilicon. Particularly, the sacrificial layer may be removed using dry etching in a follow-up process.

The lower electrode 120 is formed above the air-gap portion 110-1 where the sacrificial layer exists in the substrate cavity. The lower electrode 120 is formed by depositing a certain material above the substrate 110 and patterning the deposited material. A material used for the lower electrode 120 includes a general conductive material such as a metal, and preferably, may include one of aluminum (Al), tungsten (W), gold (Au), platinum (Pt), nickel (Ni), titanium (Ti), chrome (Cr), palladium (Pd), ruthenium (Ru), rhenium (Re), and molybdenum (Mo). A thickness of the lower electrode 120 may be 10 to 1,000 nm.

The piezoelectric layer 130 is formed above the lower electrode 120. The piezoelectric layer 130 may be formed by depositing a piezoelectric material above the lower electrode 120 and patterning the deposited piezoelectric material. As a general piezoelectric material, aluminum nitride (AIN) or zinc oxide (ZnO) may be used. As a deposition method, a radio frequency (RF) magnetron sputtering method, an evaporation method, and the like are used. A thickness of the piezoelectric layer 130 may be 5 to 500 nm.

The piezoelectric layer 130 may include a piezoelectric cavity 130-1 formed between the lower electrode 120 and the upper electrode 140. Here, the piezoelectric cavity 130-1 may be formed below an electrode edge 140-1, 140-2, or 140-3 corresponding to an end of the upper electrode 140.

The piezoelectric cavity 130-1 is formed by forming a void portion by etching a part of a top of the piezoelectric layer 130, depositing and planarizing a sacrificial layer above the void portion, depositing the upper electrode 140 above the piezoelectric layer 130 including the sacrificial layer, and then removing the sacrificial layer. Here, the sacrificial layer is formed using a material such as polysilicon, TEOS, PSG, and the like, which has excellent surface roughness and is easily formed or removed.

Here, the piezoelectric cavity 130-1 may form the void portion that is a partial air space through which a bottom of the upper electrode 140 is partially exposed and a top of the lower electrode 120 is not exposed. That is, the piezoelectric cavity 130-1 may include the void portion having an exposed top surface formed to expose a part of a lower side of the electrode edge 140-1, 140-2, or 140-3 and a closed bottom surface formed not to expose an upper side of the lower electrode 120.

The piezoelectric cavity 130-1 is formed below the electrode edge 140-1, 140-2, or 140-3 corresponding to the end of the upper electrode 140. Here, since the upper electrode 140 has a structure which does not surround an overall top surface of the piezoelectric cavity 130-1 but surrounds only a part of the piezoelectric cavity 130-1, the piezoelectric cavity 130-1 may be formed by opening a part of the void portion.

The piezoelectric cavity 130-1 may have a cavity area formed by a cavity bottom surface 130-11 with a partially exposed top of the piezoelectric layer 130, a cavity inner wall 130-12 vertically formed inside the upper electrode 140 on the basis of the electrode edge 140-1, 140-2, or 140-3, and a cavity outer wall 130-13 vertically formed outside the upper electrode 140.

A height of the piezoelectric cavity 130-1 may be smaller than or equal to half a thickness of the piezoelectric layer 130. The piezoelectric cavity 130-1 is formed so that a thickness of the piezoelectric layer 130 varies in each area. The height of the piezoelectric cavity 130-1 may be formed to be smaller than or equal to half the thickness of the piezoelectric layer 330 so as to provide a minimum thickness which allows heat generated inside to be easily released. Also, a lateral width of the piezoelectric cavity 130-1 may be greater than or equal to a quarter of a wavelength of energy discharged through the piezoelectric layer 130.

The upper electrode 140 is formed above the piezoelectric layer 130. When the piezoelectric cavity 130-1 is formed in the piezoelectric layer 130 and the sacrificial layer is formed therein, the upper electrode 140 may be formed above a part of a top of the sacrificial layer. The upper electrode 140 may be formed by depositing a metal film for an upper electrode in a certain area above the piezoelectric layer 130 and patterning the deposited metal film. The same material, same deposition method, and same patterning method as those of the lower electrode 120 may be used for forming the upper electrode 140. A thickness of the upper electrode 140 may be 5 to 1000 nm.

The electrode edge 140-1, 140-2, or 140-3 is formed at an end of one side of the upper electrode 140. The electrode edge 140-1, 140-2, or 140-3 may be an electrode structure having a relatively greater electrode thickness in comparison to other electrode structures included in the upper electrode 140. The electrode edge 140-1, 140-2, or 140-3 corresponds to an edge frame of the upper electrode 140 and performs a function of blocking energy escaping through a side surface part.

Here, when the air-gap type FBAR 100 corresponds to a quadrangular structure, a distance between the electrode edge 140-1, 140-2, or 140-3 and the cavity inner wall 130-12 on a vertical cross section with respect to each of sides in the quadrangular structure differs for each of the sides.

Referring to FIG. 2A, a distance D1 between the cavity inner wall 130-12 and the electrode edge 140-1 on one side AA′ of the air-gap type FBAR 100 is relatively short. Also, referring to FIG. 2B, a distance D2 between the cavity inner wall 130-12 and the electrode edge 140-2 on another side BB′ of the air-gap type FBAR 100 protrudes relatively longer. Also, referring to FIG. 2C, a distance D3 between the cavity inner wall 130-12 and the electrode edge 140-3 on still another side CC′ of the air-gap type FBAR 100 protrudes longest.

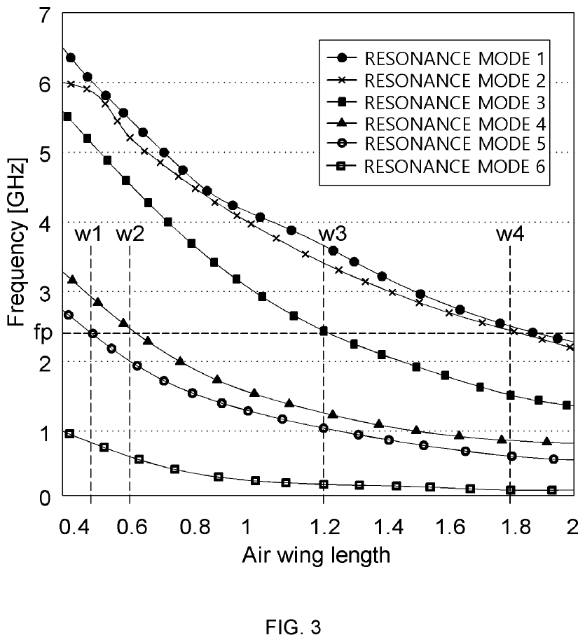

FIG. 3 is a graph illustrating that it is possible to adjust a distance between a cavity inner wall and an electrode edge according to a resonance mode.

Referring to FIG. 3, when a desired frequency fp is given, the distance (air wing length) between the cavity inner wall and the electrode edge may be variously set according to resonance modes 1 to 6. That is, since the air-gap type FBAR is formed so as to form the distance between the electrode edge and the cavity inner wall of the piezoelectric cavity to differ for each of sides of the quadrangular structure, an error in a process of manufacturing an air-gap type FBAR having a plurality of resonance modes may be easily corrected by adjusting the distance between the cavity inner wall and the electrode edge as well as improving a quality factor.

The protective layer 150 is located above the upper electrode 140. The protective layer 150 performs a passivation function to protect the lower electrode 120, the piezoelectric layer 130, and the upper electrode 140.

A protective edge 150-1 corresponding to an end of the protective layer 150 may coincide with an end of the electrode edge 140-1, 140-2, or 140-3 as shown in FIGS. 2A to 2C.

Accordingly, due to the components, the upper electrode 140 and the protective layer 150 may be exposed to the air to form a cantilever and a lateral wave escaping from an active area may be locked up using resonance of the cantilever so as to increase a quality factor as shown in FIG. 2A.

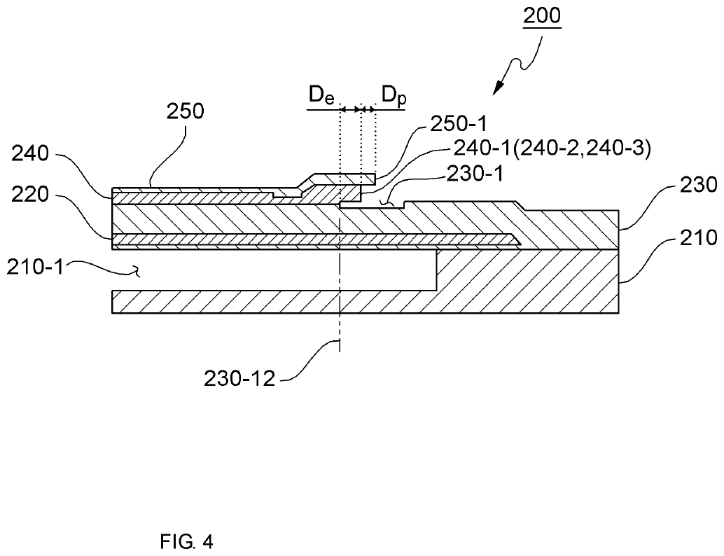

FIG. 4 is a vertical cross-sectional view of an air-gap type FBAR 200 according to a second embodiment of the present invention.

Referring to FIG. 4, the air-gap type FBAR 200 according to the second embodiment includes a substrate 210, an air-gap portion 210-1, a lower electrode 220, a piezoelectric layer 230, an upper electrode 240, and a protective layer 250.

Here, since functional features with respect to the substrate 210, the air-gap portion 210-1, the lower electrode 220, the piezoelectric layer 230, the upper electrode 240, and the protective layer 250 correspond to the substrate 110, the air-gap portion 110-1, the lower electrode 120, the piezoelectric layer 130, the upper electrode 140, and the protective layer 150 which are shown in FIG. 2C, a detailed description thereof will be omitted and unique characteristics of the second embodiment will be mainly described below.

A protective edge 250-1 corresponding to an end of the protective layer 250 does not coincide with an end of an electrode edge 240-1.

In FIG. 4, the protective edge 250-1 may be a part of the protective layer 250 which protrudes by a certain length or longer from the electrode edge 240-1 (refer to FIG. 4), and the upper electrode 240 may protrude (not shown) by a certain length or longer from the protective edge 250-1.

Here, the certain length may be a length Dp increasing within a range of 50% of a protruding length De of the upper electrode 240 from the cavity inner wall 230-12.

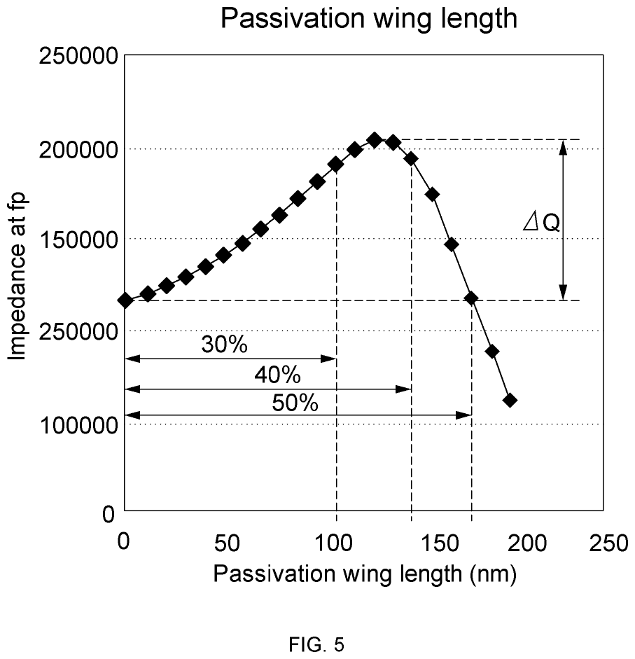

FIG. 5 is a graph illustrating an improvement degree of a quality factor according to a protruding length of the protective edge 250-1 of the protective layer.

Referring to FIG. 5, there is shown a state the quality factor increases when the protruding length (passivation wing length) of the protective edge 250-1 of the protective layer is 50% of a protruding length of the upper electrode 240. Preferably, it may be seen that an optimum quality factor is obtained when the protruding length of the protective edge 250-1 of the protective layer is 30% to 40% of the protruding length of the upper electrode 240.

That is, when the protective layer 250 protrudes from the electrode edge 240-1 by a certain length or longer or the upper electrode 240 protrudes from the protective edge 250-1 by a certain length or longer, in comparison to a case in which the protective edge 250-1 of the protective layer coincides with the electrode edge 240-1 of the upper electrode 240, a quality factor may increase by ΔQ and an insertion loss and a skirt property of a filter may be improved.

According to the present invention, since a substrate, a lower electrode, a piezoelectric layer, and an upper electrode are included and the piezoelectric layer forms a piezoelectric cavity below an electrode edge of the upper electrode, the upper layer and a passivation layer are exposed to the air and form a cantilever and resonance of the cantilever is used to lock up a lateral wave escaping from an active area so as to increase a quality factor.

Also, since a distance between an electrode edge and a cavity inner wall of a piezoelectric cavity is formed to be different on a vertical cross section with respect to each of sides in a polygonal structure of an air-gap type FBAR, a quality factor may be increased. The distance between the electrode edge and the cavity inner wall in the air-gap type FBAR including a plurality of resonance modes may be easily adjusted so as to minimize an error in a process of manufacturing the air-gap type FBAR.

The exemplary embodiments of the present invention have been described above. It should be understood by one of ordinary skill in the art that modifications may be made without departing from the essential features of the present invention. Therefore, the disclosed embodiments should be considered not in a limitative view but a descriptive view. The scope of the present invention will be shown in the claims not in the above description, and all differences within an equivalent range thereof should be construed as being included in the present invention.

What is claimed is:

1. An air-gap type film bulk acoustic resonator (FBAR) comprising:
a substrate comprising an air-gap portion which has a substrate cavity and is formed in a top surface;
a lower electrode formed above the substrate;
a piezoelectric layer formed above the lower electrode; and
an upper electrode formed above the piezoelectric layer and having one side on which an electrode edge is formed to be adjacent to a vertical virtual boundary of a sidewall of the air-gap portion,
wherein the piezoelectric layer comprises a piezoelectric cavity formed below the electrode edge.

2. The air-gap type FBAR of claim 1, wherein the piezoelectric cavity comprises a cavity area formed by a cavity bottom surface formed by exposing a part of a top of the piezoelectric layer, a cavity inner wall vertically formed inside the upper electrode on the basis of the electrode edge, and a cavity outer wall vertically formed outside the upper electrode.

3. The air-gap type FBAR of claim 2, wherein a distance between the cavity inner wall and the electrode edge on a vertical cross section with respect to each of sides in a polygonal structure of the air-gap type FBAR is different for each of the sides.

4. The air-gap type FBAR of claim 2, further comprising a protective layer formed above the upper electrode.

5. The air-gap type FBAR of claim 4, wherein a protective edge corresponding to an end of the protective layer coincides with an end of the electrode edge.

6. The air-gap type FBAR of claim 4, wherein a protective edge corresponding to an end of the protective layer does not coincide with an end of the electrode edge.

7. The air-gap type FBAR of claim 6, wherein the protective layer protrudes from the electrode edge by a certain length or longer or the upper electrode protrudes from the protective edge by a certain length or longer.

8. The air-gap type FBAR of claim 7, wherein the certain length is a length increased or decreased within a range of 50% of a protruding length of the upper electrode protruding from the cavity inner wall.
